(19) United States
(12) Patent Application Publication
(10) Pub. No.: US 2017/0370769 A1
(43) Pub. Date: Dec. 28, 2017

(54) SOLID-STATE IMAGE SENSOR AND IMAGING DEVICE USING SAME

(71) Applicant: Panasonic Intellectual Property Management Co., Ltd., Osaka (JP)

(72) Inventors: TAKUYA ASANO, Hyogo (JP); YOSHINOBU SATO, Osaka (JP)

(21) Appl. No.: 15/682,546

(22) Filed: Aug. 22, 2017

Related U.S. Application Data
(63) Continuation of application No. PCT/JP2016/000262, filed on Jan. 20, 2016.

(30) Foreign Application Priority Data
Mar. 26, 2015 (JP) 2015-064798

(51) Int. Cl. G01J 1/42; G01S 7/486; G01J 1/44; H04N 5/378; H01L 27/148

(52) U.S. Cl. CPC G01J 1/4228; H04N 5/378; H01L 27/14875; G01J 1/44; G01S 7/486; H01L 27/14856; G01J 2001/448

(57) ABSTRACT

A solid-state image sensor including photoelectric conversion parts having a vertical overflow drain structure is made usable as, for example, a distance measuring sensor with high accuracy. In the solid-state image sensor, a pixel array part is formed in a well region of a second conductive type formed at a surface part of a semiconductor substrate of a first conductive type. In the pixel array part, photoelectric conversion parts each of which converts incident light into signal charges and has the vertical overflow drain structure (VOD) are arranged in a matrix form. Substrate discharge pulse signal φSub for controlling potential of the VOD is applied to a signal terminal. An impurity induced part into which impurity of the first type is induced is formed below a connecting part in the semiconductor substrate.

### TECHNICAL FIELD

The present disclosure relates to a solid-state image sensor used, for example, in a distance measuring camera.

### BACKGROUND ART

PTL 1 discloses a distance measuring camera having a function for measuring a distance to a subject using infrared light. In general, a solid-state image sensor used in the distance measuring camera is referred to as a distance measuring sensor. Particularly, a camera that is mounted on a game machine and detects movement of a body or hands of a person who is the subject is also referred to as a motion camera.

PTL 2 discloses a solid-state imaging device having a vertical transfer electrode structure that can simultaneously read all pixels. Specifically, the solid-state imaging device is a charge-coupled device (CCD) image sensor provided with a vertical transfer part extending in a vertical direction adjacent to each column of photo diodes (PD).

The vertical transfer part includes four vertical transfer electrodes corresponding to each photo diode. At least one of the vertical transfer electrodes is used as a read electrode for reading signal charges from the photo diodes to the vertical transfer part, and is provided with a vertical overflow drain (VOD) to sweep out signal charges in all photo diodes in the pixels.

### CITATION LIST

### Patent Literature

PTL1: Unexamined Japanese Patent Publication No. 2009-174854

PTL2: Unexamined Japanese Patent Publication No. 2000-236486

### SUMMARY OF THE INVENTION

A case in which the solid-state imaging device in PTL 2 is used as a distance measuring sensor is assumed. For example, a subject is irradiated with infrared light and is captured for a predetermined exposure time period by the distance measuring camera. In such a way, signal charges generated by reflected light are obtained. Here, the speed of light is approximately 30 cm per 1 ns, and the infrared light returns from an object located apart from the distance measuring sensor by 1 m when approximately 7 ns elapses after the infrared light has been emitted, for example. Therefore, control of an exposure time period of an extremely short time, for example, 10 ns to 20 ns is important to obtain high distance accuracy.

On the other hand, for the control of the exposure time period, a method that uses a substrate discharge pulse signal that controls potential of a vertical overflow drain can be considered. In this case, the substrate discharge pulse signal requires accuracy of several nanoseconds. In other words, when waveform distortion or delay of a nanosecond order is produced in the substrate discharge pulse signal, signal charges generated by the reflected light cannot be obtained correctly, and therefore a possibility to cause an error in distance measurement is increased.

An object of the present disclosure is to allow a solid-state image sensor provided with a photoelectric conversion part having the vertical overflow drain structure to be used as, for example, a distance measuring sensor with high accuracy.

In an aspect of the present disclosure, a solid-state image sensor is formed in a semiconductor substrate of a first conductive type and a well region of a second conductive type formed at a surface part of the semiconductor substrate. The solid-state image sensor includes a pixel array part, a first signal terminal, a signal wiring pattern, and a connecting part. In the pixel array part, photoelectric conversion parts each of which converts incident light into signal charges and has a vertical overflow drain structure are arranged in a matrix form. The first signal terminal receives a substrate discharge pulse signal for controlling potential of the vertical overflow drain structure. The signal wiring pattern transmits the substrate discharge pulse signal applied to the first signal terminal. The connecting part electrically connects the signal wiring pattern to a portion other than the well region on the surface of the semiconductor substrate. In the solid-state image sensor, an impurity induced part into which impurity of the first conductive type is induced is formed below the connecting part in the semiconductor substrate.

According to this aspect, the impurity induced part into which impurity of the first conductive type is induced is formed below the connecting part that supplies the substrate discharge pulse signal to the semiconductor substrate. Therefore, in a path in which the substrate discharge pulse signal is transferred to the photoelectric conversion part through the inside of the semiconductor substrate, a resistance in a direction perpendicular to the surface of the substrate can be significantly reduced. With this configuration, waveform distortion and delay in the pulsed substrate-discharge signal that reaches the photoelectric conversion parts can be suppressed. Accordingly, when the solid-state image sensor is used as the distance measuring sensor, an amount of a signal generated by the reflected light can be measured correctly, and therefore an error contained in a measured distance can be reduced.

The solid-state image sensor according to the aspect described above is used as a time-of-flight (TOF) type distance measuring sensor, and the substrate discharge pulse signal is used to control the exposure time period.

Furthermore, in another aspect of the present disclosure, an imaging device includes an infrared light source for irradiating a subject with infrared light, and the solid-state image sensor in the above aspect for receiving reflected light from the subject.

According to the present disclosure, waveform distortion and delay in the substrate discharge pulse signal that reaches the photoelectric conversion parts can be suppressed, and therefore the solid-state image sensor can be used as a highly accurate distance measuring sensor, for example.

### BRIEF DESCRIPTION OF DRAWINGS

FIG. 1 is a schematic sectional view illustrating a configuration of a solid-state image sensor according to an exemplary embodiment.

FIG. 2 is a schematic plan view illustrating a configuration example of a solid-state image sensor according to a first exemplary embodiment.

FIG. 3 is a schematic diagram illustrating a configuration example using a distance measuring camera.

FIG. 4 is a diagram explaining a distance measuring method by using a time-of-flight (TOF) type distance measuring camera.

FIG. 5 is a timing chart illustrating a relationship between irradiated light and reflected light in the TOF type distance measuring camera.

FIG. 6A is a diagram explaining an operation principle of the TOF type distance measuring camera.

FIG. 6B is a diagram explaining the operation principle of the TOF type distance measuring camera.

FIG. 7 is a timing chart illustrating an example for controlling an exposure time period by using φSub.

FIG. 8 is a timing chart illustrating an example for controlling the exposure time period by using φSub and φV.

FIG. 9A is a timing chart when waveform distortion is large in FIG. 7.

FIG. 9B is a timing chart when waveform delay occurs in FIG. 7.

FIG. 10A is a timing chart when waveform distortion is large in FIG. 8.

FIG. 10B is a timing chart when waveform delay occurs in FIG. 8.

FIG. 11 is a diagram illustrating an arrangement example of signal terminals to which φSub is applied.

FIG. 12 is a diagram illustrating an arrangement example of signal terminals to which φV is applied.

FIG. 13 is a diagram illustrating an arrangement example of signal terminals to which φV is applied.

FIG. 14 is a schematic plan view illustrating a configuration example of a solid-state image sensor according to a second exemplary embodiment.

FIG. 15A is a schematic sectional view illustrating a part of a manufacturing process of a solid-state image sensor according to a third exemplary embodiment.

FIG. 15B is a schematic sectional view illustrating an entire configuration of the solid-state image sensor according to the third exemplary embodiment.

### DESCRIPTION OF EMBODIMENTS

Hereinafter, exemplary embodiments will be described with reference to drawings. The description will be made with reference to the attached drawings, but the description intends to give examples, and the present disclosure is not limited by the examples. In the drawings, elements representing substantially the same configuration, operation, and effect are attached with the same reference sign.

### First Exemplary Embodiment

In a first exemplary embodiment, a solid-state image sensor is assumed to be a charge-coupled device (CCD) image sensor. Here, an interline transfer type CCD that corresponds to full pixel reading (progressive scan) will be described as an example.

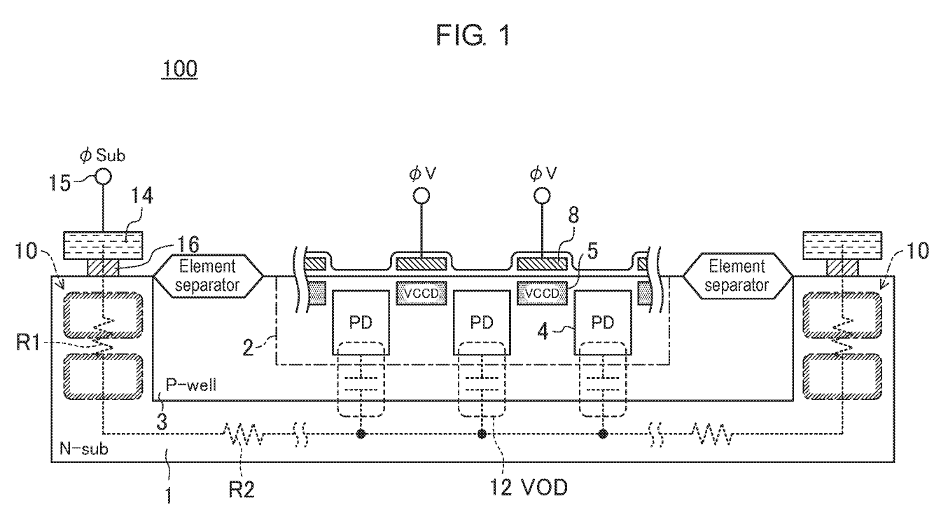

FIG. 1 is a schematic sectional view illustrating a configuration of solid-state image sensor 100 according to the first exemplary embodiment. Illustration of components that do not directly relate to the description of the present disclosure such as a microlens or an intermediate film disposed above a wiring layer is omitted for simplification of the description.

In the configuration illustrated in FIG. 1, semiconductor substrate 1 is a silicon substrate of an N-type as a first conductive type. Well region 3 of a P-type as a second conductive type (hereafter, referred to as P well region) is formed at a surface part of one surface of semiconductor substrate 1. In P well region 3, pixel array part 2 provided with photoelectric conversion parts (PD) 4 each of which converts incident light into signal charges, and vertical transfer parts (VCCD) 5 each of which reads and transmits the signal charges generated in each of photoelectric conversion parts 4 is formed. Photoelectric conversion parts 4 and vertical transfer parts 5 are an N-type diffusion region. Photoelectric conversion parts 4 are arranged in a matrix form, and each of vertical transfer parts 5 is disposed between columns of photoelectric conversion parts 4, although illustration thereof is simplified in FIG. 1. FIG. 1 is the sectional view made by cutting pixel array part 2 in a row direction. In pixel array part 2, pixels are configured by combining photoelectric conversion parts 4 and vertical transfer parts 5. In vertical transfer parts 5, accumulation (storage) and non-accumulation (barrier) of the signal charges are controlled by electrode driving signal φV (hereafter, simply referred to as φV, as appropriate) applied to vertical transfer electrodes 8 for each gate, and reading of signals from photoelectric conversion parts 4 to vertical transfer parts 5 is also controlled by signal φV.

Each of photoelectric conversion parts 4 has vertical overflow drain structure 12. The vertical overflow drain structure (VOD) is a structure capable of sweeping out the charges generated in photoelectric conversion parts 4 through a potential barrier formed between photoelectric conversion parts 4 and semiconductor substrate 1. Reference sign 15 indicates a first signal terminal for applying substrate discharge pulse signal φSub (hereafter, simply referred to as φSub, as appropriate) for controlling potential of VOD 12. Reference sign 14 indicates a signal wiring pattern for transferring φSub applied to first signal terminal 15. Reference sign 16 indicates a contact as a connecting part that electrically connects signal wiring pattern 14 with a portion other than P well region 3 on a surface of semiconductor substrate 1. Signal wiring pattern 14 is, for example, a metallic wiring pattern such as aluminum.

When a high voltage is applied as φSub to first signal terminal 15, signal charges in all pixels are collectively discharged into semiconductor substrate 1. Further, the potential barrier in vertical overflow drain structure 12 can be controlled by φSub. To help understanding, in FIG. 1, a path in which φSub applied to first signal terminal 15 is transferred to photoelectric conversion parts 4 through the inside of semiconductor substrate 1 is schematically illustrated by using broken lines. Resistance R1 indicates an electric resistance in a direction perpendicular to the surface of the substrate, and resistance R2 indicates an electric resistance in a direction parallel to the surface of the substrate (horizontal direction).

In the present exemplary embodiment, impurity induced parts 10 into which N-type impurity is induced are formed below contact 10. Those can significantly reduce resistance R1 in the path through which φSub is transmitted. Impurity induced parts 10 can be formed by, for example, performing N-type ion implantation up different depths several times. FIG. 1 schematically illustrates a configuration example in which N-type ions (for example, arsenic or phosphorus) are implanted up two different depths. For example, the N-type ions are preferably implanted up a depth not less than 1 μm from the surface of the substrate.

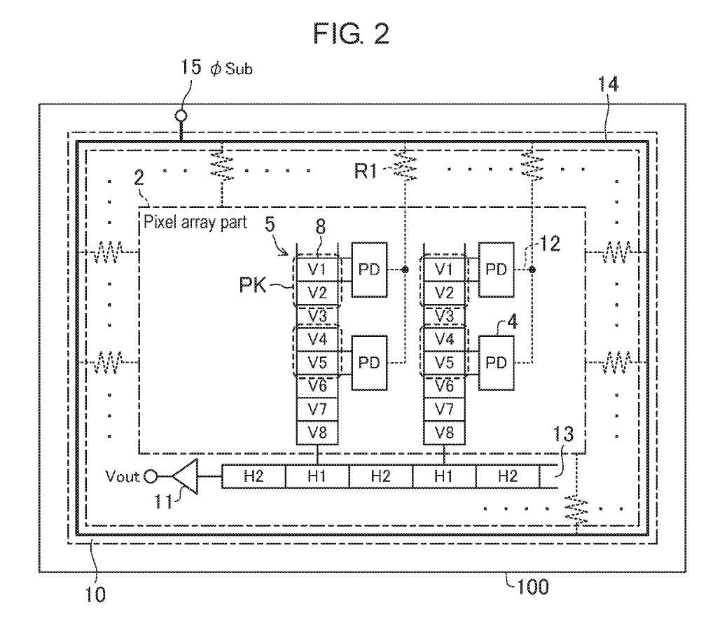

FIG. 2 is a schematic plan view of a configuration example of the solid-state image sensor according to the present exemplary embodiment. In order to simplify the diagram, FIG. 2 illustrates only two pixels in a horizontal direction and two pixels in a vertical direction as pixel array part 2. The sectional configuration illustrated in FIG. 1 corresponds to a configuration that is cut so as to pass through photoelectric conversion parts 4 in a lateral direction in FIG. 2. Reference sign 13 indicates a horizontal transfer part that transfers signal charges transferred by vertical transfer parts 5 in the row direction (horizontal direction). Reference sign 11 indicates a charge detection part that outputs the signal charges transferred by horizontal transfer part 13. In vertical transfer parts 5, for example, one pixel includes four gates included in vertical transfer electrodes 8 and vertical transfer parts 5 are eight-phase driven in a unit of two pixels. Horizontal transfer part 13 is two-phase driven, for example. The signal charges accumulated in each of photoelectric conversion parts 4 are read by electrodes indicated as signal packet PK, for example, and are transferred.

In FIG. 2, VOD 12 is illustrated in a lateral direction of each of the pixels for convenience of illustration, but actually VOD 12 is configured in a bulk direction of the pixel (a depth direction of semiconductor substrate 1), as described in FIG. 1. Signal wiring pattern 14 that transfers φSub is disposed so as to surround pixel array part 2 in order to enhance uniformity in a chip surface (between the pixels). Contact 16 (not illustrated in FIG. 2) is appropriately disposed between signal wiring pattern 14 and semiconductor substrate 1, and impurity induced parts 10 are formed below contact 16. In FIG. 2, impurity induced parts 10 are formed so as to surround pixel array part 2. A region where signal wiring pattern 14 is disposed is sufficiently wider than a pixel size (about several μm) and the like. Therefore, photolithography and the like for forming impurity induced parts 10 do not need accuracy as high as that when a fine cell is formed. For this reason, by forming impurity induced parts 10, resistance R1 in the path through which φSub is transmitted can be reduced at a low cost.

The solid-state image sensor according to the present exemplary embodiment is used as a distance measuring sensor, for example, a time-of-flight (TOF) type distance measuring sensor. Hereinafter, the TOF type distance measuring sensor will be described.

### <TOF Type Distance Measuring Sensor>

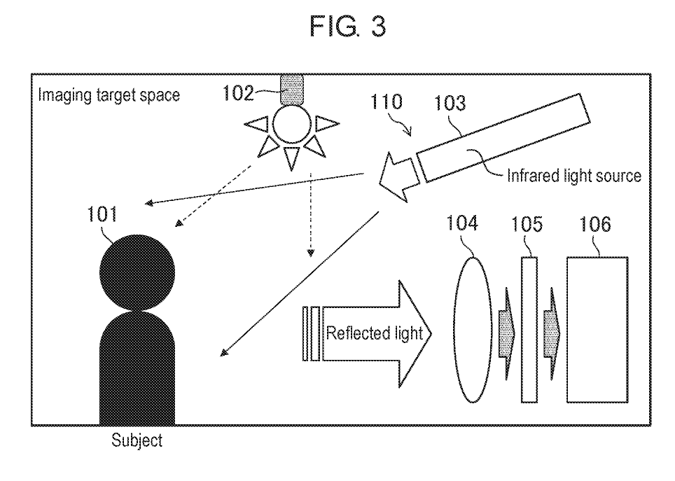

FIG. 3 is a schematic diagram illustrating a configuration example using a distance measuring camera. In FIG. 3, imaging device 110 used as the distance measuring camera includes infrared light source 103 that emits infrared laser light, optical lens 104, optical filter 105 that transmits light of a near infrared wavelength region, and solid-state image sensor 106 used as the distance measuring sensor. In an imaging target space, subject 101 is irradiated with infrared laser light having, for example, a wavelength of 850 nm from infrared light source 103 under background-light illumination 102. Solid-state image sensor 106 receives reflected light through optical lens 104 and optical filter 105 that transmits the light of the near infrared wavelength region, for example, near 850 nm. An image that is imaged on solid-state image sensor 106 is converted into an electric signal. As solid-state image sensor 106, solid-state image sensor 100 according to the present exemplary embodiment, which is a CCD image sensor for example, is used.

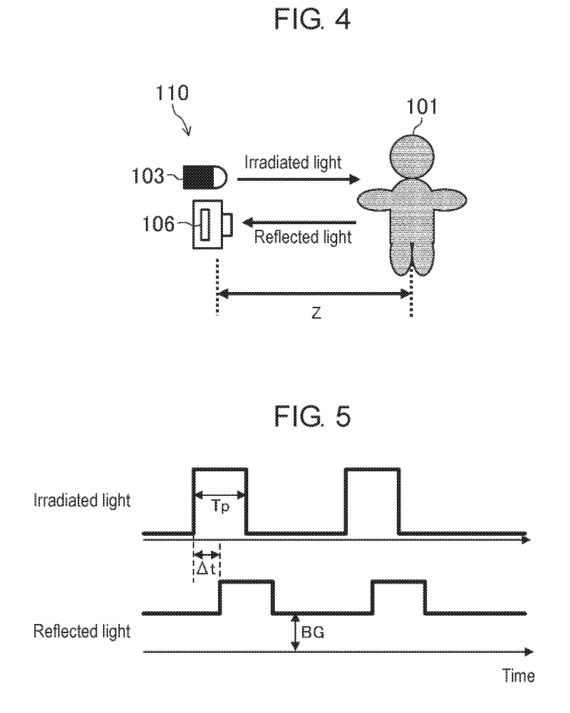

FIG. 4 is a diagram explaining a distance measuring method by using the TOF type distance measuring camera. Imaging device 110 used as the distance measuring camera is disposed so as to face subject 101. A distance from imaging device 110 to subject 101 is Z. Infrared light source 103 contained in imaging device 110 gives a pulse-shaped irradiated light to subject 101 located at a position apart from imaging device 110 by distance Z. The irradiated light reaches subject 101 and is reflected, and imaging device 110 receives the reflected light. Solid-state image sensor 106 contained in imaging device 110 converts the reflected light into an electric signal.

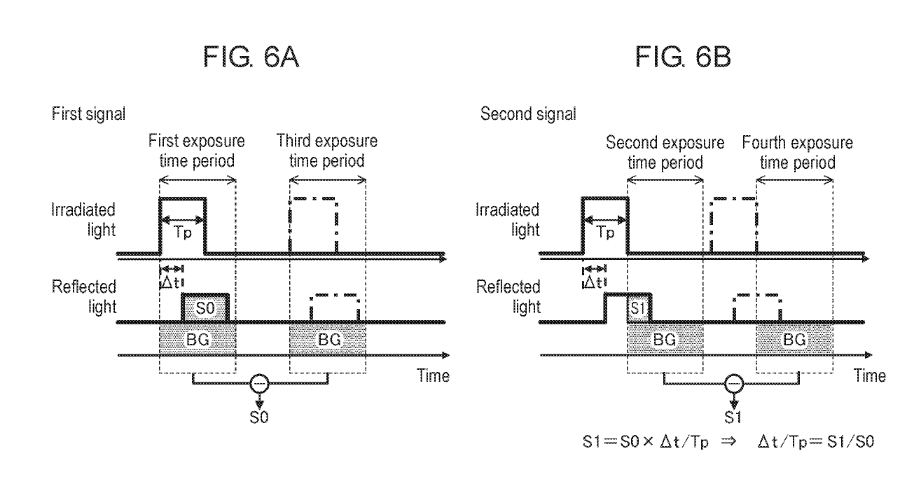

FIG. 5 is a timing chart illustrating a relationship between the irradiated light and the reflected light in the TOF type distance measuring camera. In FIG. 5, a pulse width of the irradiated light is defined as Tp, a delay between the irradiated light and the reflected light is defined as Δt, and a background light component contained in the reflected light is defined as BG. Since the reflected light contains background light component BG, background light component BG is preferably removed when distance Z is calculated.

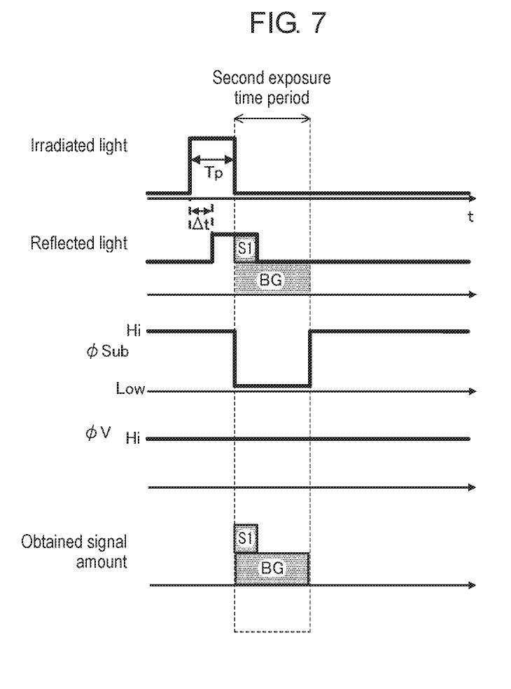

Each of FIGS. 6A, 6B is a diagram explaining an operation principle (a pulse method or a pulse modulation method) of the TOF type distance measuring camera based on the timing chart in FIG. 5. As illustrated in FIG. 6A, first an amount of signal charges generated by the reflected light during a first exposure time period started from a rising time of an irradiated light pulse is S0+BG. Further, an amount of signal charges generated by only the background light during a third exposure time period in which the infrared light is not irradiated is BG. Accordingly, by calculating a difference between the two amounts, magnitude of a first signal obtained by solid-state image sensor 106 becomes S0. On the other hand, as illustrated in FIG. 6B, an amount of signal charges generated by the reflected light during a second exposure time period started from a falling time of the irradiated light pulse is S1+BG. Further, an amount of signal charges generated by only the background light during a fourth exposure time period in which the infrared light is not irradiated is BG. Accordingly, by calculating a difference between the two amounts, magnitude of a second signal obtained by solid-state image sensor 106 becomes S1.

Assuming that the speed of light is c, distance Z to subject 101 is calculated by Equation 1 below.

$$Z = C \times \frac{Δ t}{2} = \frac{C \cdot {T}_{P}}{2} \times \frac{S 1}{S 0}$$

Here, dispersion σ_{z} of distance measurement is calculated by Equation 2 below.

$${σ}_{Z} = \frac{C \cdot {T}_{P}}{2} \cdot ( \frac{S 1}{S 0} ) \times \sqrt{{( \frac{{σ}_{S 1}}{S 1} )}^{2} + {( \frac{{σ}_{S 0}}{S 0} )}^{2}}$$

$${σ}_{S 0 , S 1} = \sqrt{S 0} , \sqrt{S 1}$$

### <Control of Exposure Time Period Using φSub and its Problems>

When the solid-state image sensor according to the present exemplary embodiment is used as the TOF type distance measuring sensor, φSub is used to control the exposure time period.

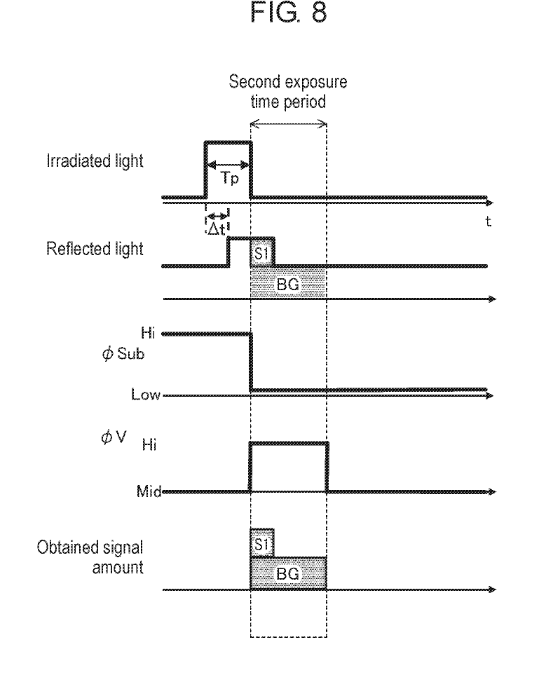

FIG. 7 is a timing chart illustrating an example for controlling the exposure time period by using φSub. In the example in FIG. 7, a start timing of the second exposure time period illustrated in FIG. 6B is defined by a fall of φSub, and an end timing is defined by a rise of φSub. When φSub is a level of Hi, potential of VOD 12 decreases, and the charges in photoelectric conversion parts 4 are discharged into semiconductor substrate 1. On the other hand, when φSub is a level of Low, potential of VOD 12 increases, and the discharging of the charges in photoelectric conversion parts 4 into semiconductor substrate 1 is blocked. Due to φSub falling at the start timing of the second exposure time period, almost all of charges in photoelectric conversion parts 4 are moved toward vertical transfer parts 5, and such a state continues until φSub rises. Accordingly, signal amount S1 caused by the reflected light in the second exposure time period can be obtained.

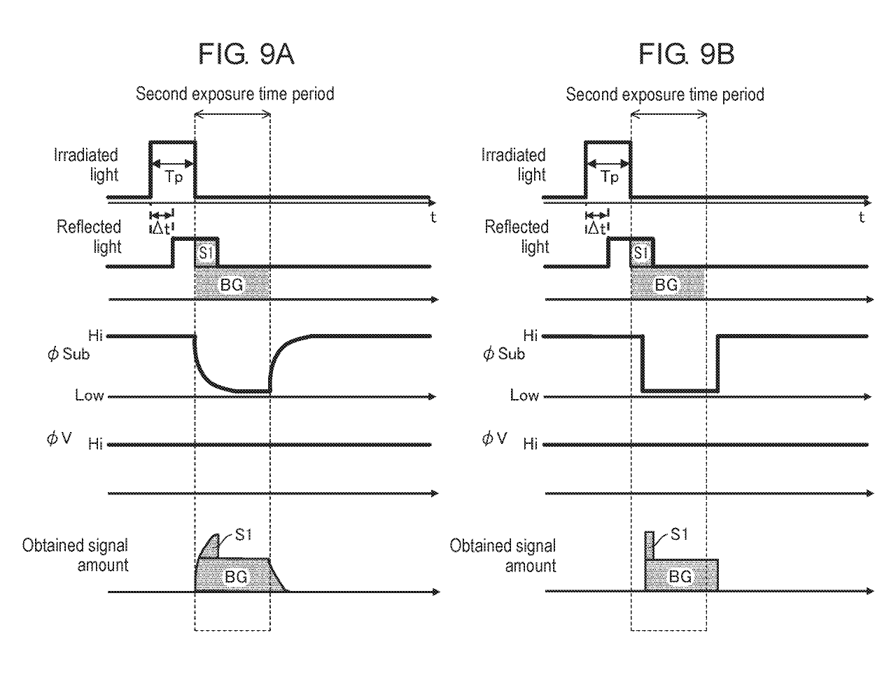

Alternatively, as illustrated in FIG. 8, φV may be used to control the exposure time period together with φSub. That is, the start timing of the second exposure time period is defined by the fall of φSub and a rise of φV, and the end timing is defined by a fall of φV. Due to φSub falling and φV rising at the start timing of the second exposure time period, almost all of charges in photoelectric conversion parts 4 are moved toward vertical transfer parts 5, and such a state continues until φV falls. Accordingly, signal amount S1 caused by the reflected light in the second exposure time period can be obtained.

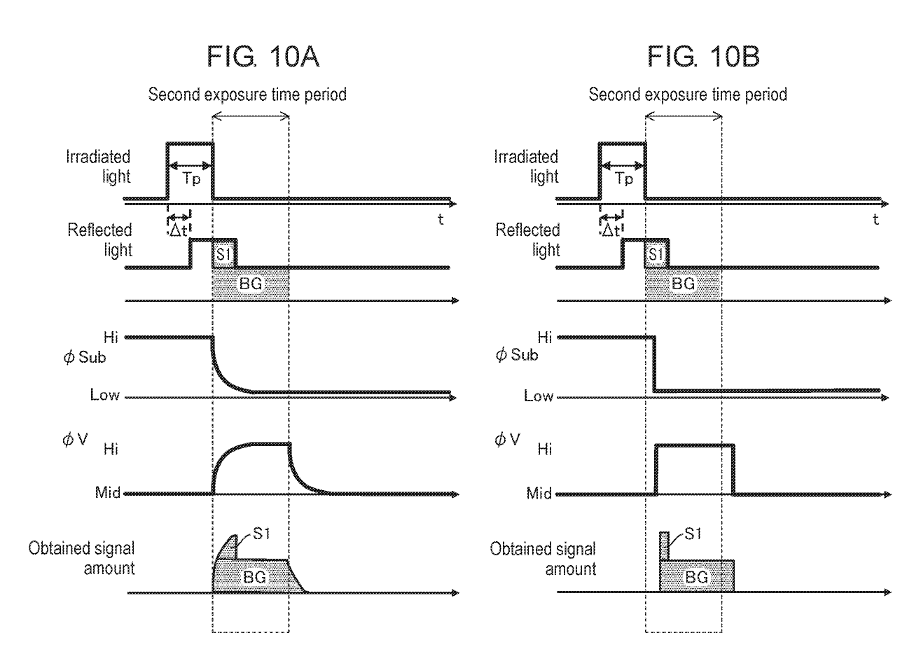

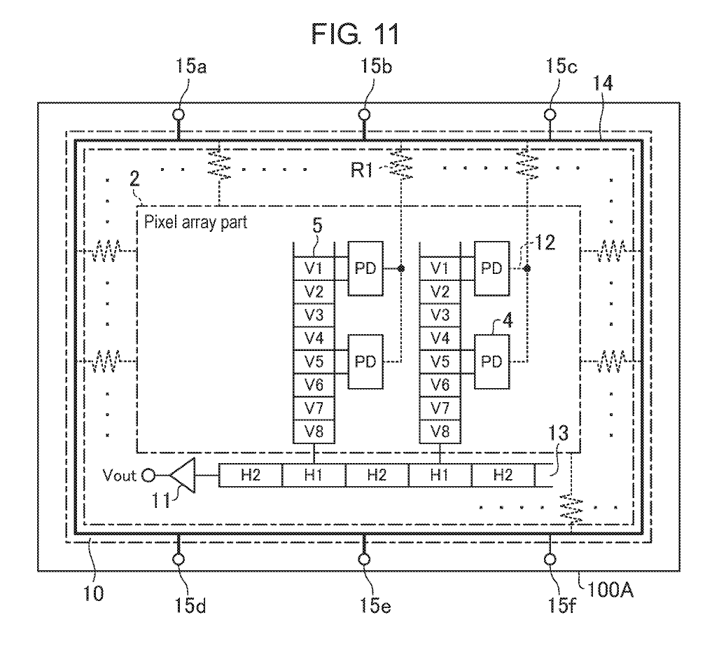

Here, according to studies conducted by inventors of the present application, the following problems are recognized. In the TOF method, pulse width Tp of the irradiated light is extremely short, that is approximately several ten ns. Therefore, a pulse for controlling the exposure time period requires accuracy of several ns. For example, in the exposure time period control illustrated in FIG. 7, when waveform distortion of φSub is large, a state illustrated in FIG. 9A is caused, and therefore signal amount S1 is not obtained correctly. Further, when φSub delays, a state illustrated in FIG. 9B is caused, and signal amount S1 is not obtained correctly also in this case. Therefore, an error is easily caused in distance calculation. Similarly, in the exposure time period control illustrated in FIG. 8, when waveform distortion of φSub and φV is large, a state illustrated in FIG. 10A is caused, and when φSub and φV delay, a state illustrated in FIG. 10B is caused. Signal amount S1 cannot be obtained correctly in both cases, and therefore an error is easily caused in distance calculation.

On the other hand, when the solid-state image sensor is used as a normal imaging device instead of the distance measuring device, φSub is used for reset operations of photoelectric conversion parts 4 (discharge into the substrate) that are performed in every frame, for example. In this case, φSub has only to be applied to the solid-state image sensor 60 times per second, for every frame time period of about 16.7 ms. Accordingly, pulse φSub does not require accuracy of several ns, and therefore the problems described above do not arise.

### <Features of the Present Exemplary Embodiment and Working Effects>

As described above, when φSub is used to control the exposure time period, if waveform distortion or delay is not suppressed, a signal amount generated by the reflected light cannot be measured correctly, and therefore an error is easily caused in a measured distance. In contrast, in the solid-state image sensor according to the present exemplary embodiment, as illustrated in FIGS. 1 and 2, impurity induced parts 10 into which N-type impurity is induced are formed below contact 16 that supplies φSub to semiconductor substrate 1. With this configuration, in the path in which φSub is transferred to photoelectric conversion parts 4 through semiconductor substrate 1, resistance R1 in the direction perpendicular to the surface of the substrate can be significantly reduced. Accordingly, since waveform distortion and delay of φSub can be suppressed and the signal amount generated by the reflected light can be measured correctly, the error in the measured distance can be reduced.

Here, to form the solid-state image sensor illustrated in FIG. 1, for example, P well region 3 is formed by forming an N-type epitaxial layer on the N-type substrate. Since signal wiring pattern 14 and contact 16 are formed in a limited region outside P well region 3, when impurity induced parts 10 are not formed, resistance R1 in the path of φSub easily becomes large. In the distance measuring sensor using the infrared light, sensitivity at a near infrared region is extremely important, and therefore deep photoelectric conversion parts 4 may be formed (for example, the VOD is formed into a depth of 5 μm or more) to provide high sensitivity. Accordingly, a thickness of the N-type epitaxial layer increases, and as a result, resistance R1 further increases.

Then, in order to appropriately form impurity induced parts 10, a number of times of N-type ion implantation may be changed mainly according to the thickness of the N-type epitaxial layer. As an amount of times of the N-type ion implantation up different depths increases, resistance R1 is decreased more efficiently. When a peak of impurity concentration appears in a depth direction, the peak is preferably located at a deep position of semiconductor substrate 1, in terms of propagation performance of φSub.

As described above, according to the present exemplary embodiment, impurity induced parts 10 into which the N-type impurity is induced are formed below contact 16 that supplies φSub to semiconductor substrate 1. With this configuration, in the path in which φSub is transferred to photoelectric conversion parts 4 through the inside of semiconductor substrate 1, resistance R1 in the direction perpendicular to the surface of the substrate can be significantly reduced. Accordingly, since waveform distortion and delay of φSub can be suppressed and the signal amount generated by the reflected light can be measured correctly, the error in the measured distance can be reduced. In addition, a configuration and a manufacturing method of the solid-state image sensor are not necessary to be changed more greatly than a conventional solid-state imaging sensor. Thus, the solid-state imaging sensor can be achieved at a low cost.

It is noted that, since resistance R2 in the horizontal direction also affects the waveform of φSub, a substrate having resistance as low as possible is preferably used as semiconductor substrate 1. For example, a silicon substrate having a resistance value of 0.3 Ω·cm or less may be used. When the layout in FIG. 2 is used, arrival times of φSub supplied from first signal terminal 15 to peripheral pixels and pixels in a center portion of pixel array part 2 are different from each other. Even when the time difference is only 1 ns, a difference of approximately 30 cm is possibly produced in a calculated distance. This difference is remarkably produced when a number of pixels in the solid-state image sensor is increased. By adopting the substrate having low resistance for semiconductor substrate 1, such a problem can be suppressed.

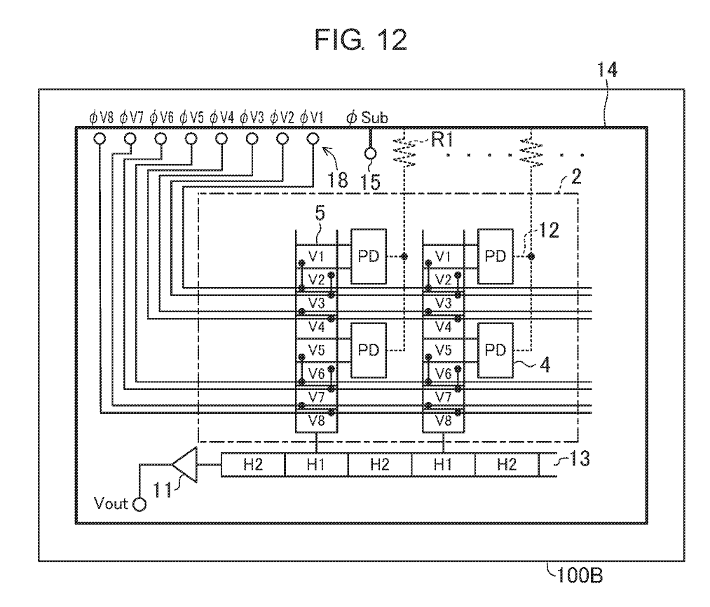

In order to suppress delay of φSub in signal wiring pattern 14, it is desirable to dispose a plurality of first signal terminals to which φSub is applied. In addition, in this case, it is desirable to dispose the plurality of first signal terminals away from one another by a uniform distance. FIG. 11 is a diagram illustrating a disposition example of the first signal terminals to which φSub is applied. In solid-state image sensor 100A in FIG. 11 in plan view, three first signal terminals 15a, 15b, 15c are approximately uniformly disposed on an upper side of pixel array part 2 in the diagram, and three first signal terminals 15d, 15e, 15f are approximately uniformly disposed on a lower side of pixel array part 2 in the diagram. In other words, the plurality of first signal terminals 15a to 15f are disposed on both sides in a column direction of pixel array part 2. With this arrangement, delay of φSub can be approximately uniformly suppressed in entire pixel array part 2, and a chip layout of solid-state image sensor 100A can be made compact. It is noted that the plurality of first signal terminals may be disposed on both sides in a row direction of pixel array part 2, that is, on right and left sides in the diagram.

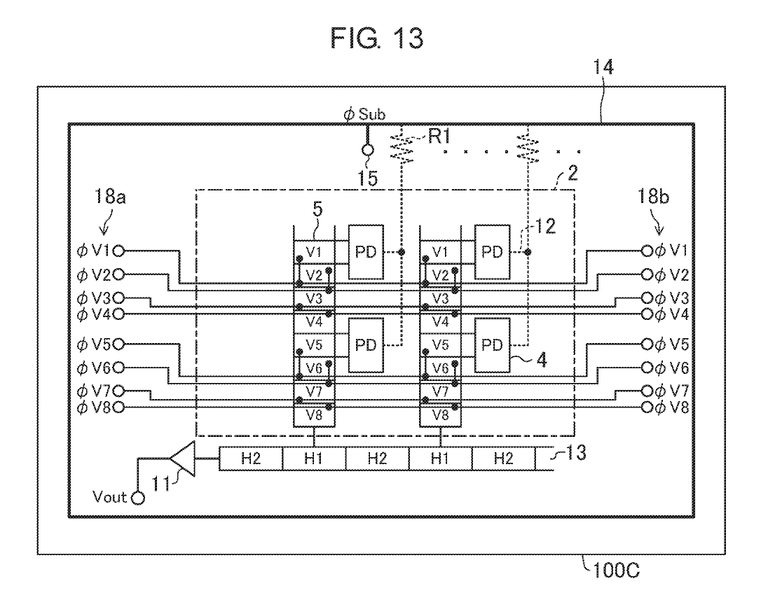

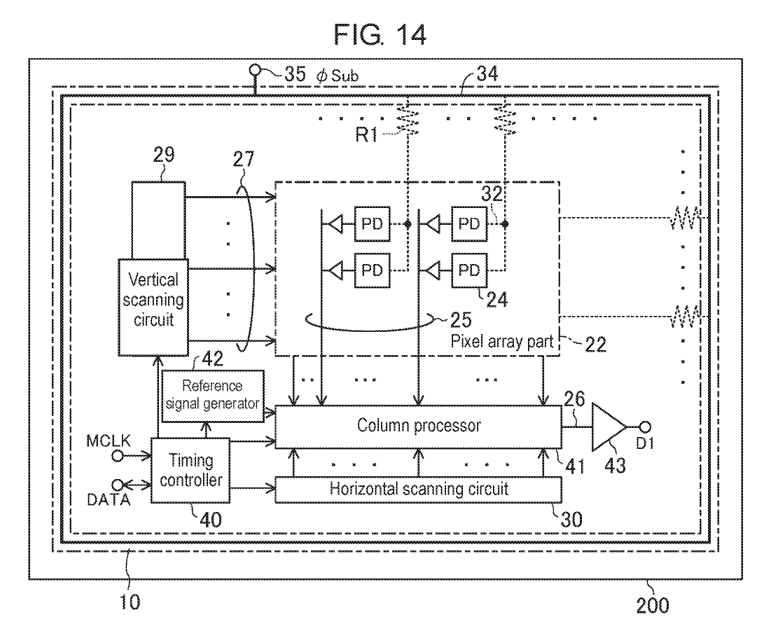

Each of FIGS. 12 and 13 illustrates a disposition example of signal terminals to which φV is applied. FIG. 12 illustrates a disposition example when the exposure time period is controlled by φSub illustrated in FIG. 7. In FIG. 12, second signal terminals 18 to which φV is applied are disposed on an upper side of solid-state image sensor 100B, that is, on the same side as first signal terminal 15 to which φSub is applied, viewed from pixel array part 2. First signal terminal 15 and second signal terminals 18 are disposed on the same side, and thus a chip area can be reduced.

On the other hand, FIG. 13 illustrates a disposition example when the exposure time period is controlled by φSub and φV illustrated in FIG. 8. In FIG. 13, second signal terminals 18a, 18b to which φV is applied are disposed on both sides in the row direction of pixel array part 2. With this disposition, since wiring patterns that transmit φV can be substantially linearly disposed, waveform distortion of φV can be suppressed. As a result, accuracy of the exposure time period control can be improved.

It is noted that, when the number of pixel of the solid-state image sensor is increased, or when the chip size of the solid-state image sensor becomes large, the plurality of first signal terminals may be disposed on four sides of pixel array part 2, that is, on a right side, a left side, an upper side, and a lower side, in any case of FIG. 11, FIG. 12, and FIG. 13. With this disposition, the delay in the wiring layer can be further suppressed.

### Second Exemplary Embodiment

In a second exemplary embodiment, the solid-state image sensor is assumed to be a complementary metal oxide semiconductor (CMOS) image sensor. However, an object of the second exemplary embodiment is to suppress waveform distortion and delay of φSub, which is the same as the object of the first exemplary embodiment. Here, a CMOS image sensor mounted with an analog-to-digital converter of a column parallel type will be described as an example. A sectional structure of the CMOS image sensor is identical to that of the first exemplary embodiment, and therefore a description of the sectional structure is omitted in the present exemplary embodiment.

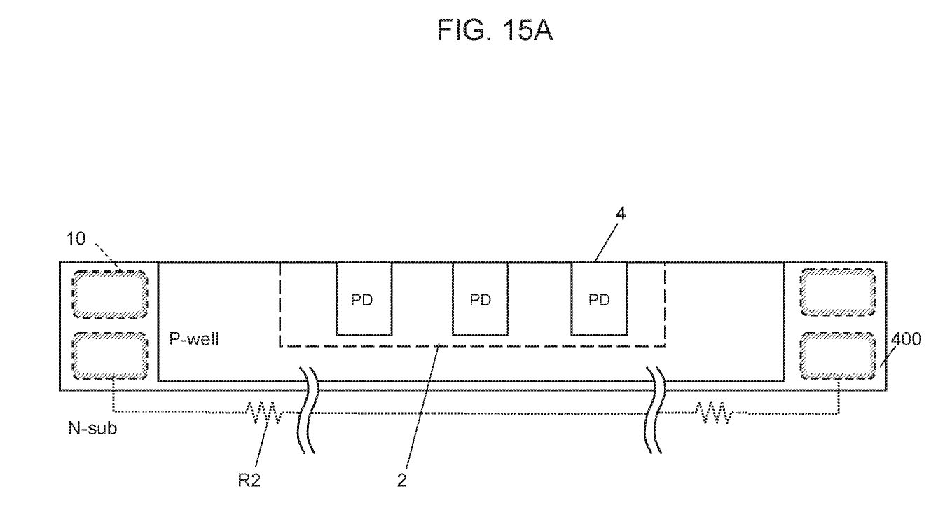

FIG. 14 is a schematic plan view illustrating an example of a configuration of a solid-state image sensor according to the present exemplary embodiment. Solid-state image sensor 200 in FIG. 14 includes pixel array part 22, vertical signal lines 25, horizontal scanning line group 27, vertical scanning circuit 29, horizontal scanning circuit 30, timing controller 40, column processor 41, reference signal generator 42, and output circuit 43. Solid-state image sensor 200 further includes a MCLK terminal that receives an input signal of a master clock signal from an external device, a DATA terminal that sends and receives commands or data to and from the external device, and a Dl terminal that transmits image data to the external device. Other than those terminals, terminals to which a power supply voltage and a ground voltage are supplied are provided.

Pixel array part 22 includes a plurality of pixel circuits arranged in a matrix form. Here, to simplify the diagram, only two pixels in a horizontal direction and two pixels in a vertical direction are illustrated. Horizontal scanning circuit 30 sequentially scans memories in a plurality of column analog-to-digital circuits in column processor 41, to output analog-to-digital converted pixel signals to output circuit 43. Vertical scanning circuit 29 scans horizontal scanning line group 27 disposed for each row of pixel circuits in pixel array part 22, in a row unit. With this configuration, vertical scanning circuit 29 selects the pixel circuits in the row unit, and causes each of the pixel circuits belonging to the selected row to simultaneously output a pixel signal to a corresponding vertical signal line 25. A number of lines of horizontal scanning line group 27 is the same as a number of rows of the pixel circuits.

Each of the pixel circuits disposed in pixel array part 22 includes photoelectric conversion part 24, and each photoelectric conversion part 24 includes vertical overflow drain structure (VOD) 32 to sweep out signal charges. Similarly to FIG. 2, VOD 32 is illustrated in a lateral direction of the pixel for convenience of illustration, but actually VOD 32 is configured in a bulk direction of the pixel (a depth direction of a semiconductor substrate). Control of VOD 32 is also similar to that of the first exemplary embodiment, and φSub supplied from first signal terminal 35 is applied to the semiconductor substrate through signal wiring pattern 34, and is used to control a potential barrier of VOD 32.

A schematic sectional view is omitted, but is similar to the schematic section view in FIG. 1. That is, also in the present exemplary embodiment similar to the first exemplary embodiment, a P well region is formed at one surface part of an N-type silicon substrate including an N-type epitaxial layer, and photoelectric conversion parts 24 are formed by using an N type diffusion region in pixel array part 22.

Here, detailed illustration of elements that have no direct relation with the present disclosure is omitted. But, when the CMOS image sensor is used as the distance measuring sensor, similarly to the CCD, it is necessary to simultaneously read signal charges in photoelectric conversion parts 24 from all pixels. Therefore, it is desirable to use a configuration that is mounted with a floating diffusion layer that temporarily retains charges read through a read transistor, or a storage part that accumulates charges in the pixel independently of the floating diffusion layer.

As understood from the configuration in FIG. 14, a number of circuits including vertical scanning circuit 29 mounted on the CMOS image sensor is larger than a number of circuits in the CCD image sensor illustrated in the first exemplary embodiment. In other words, for example when CCD and CMOS image sensors having the same pixel size and the same pixel number are compared, a chip area of the CMOS image sensor is larger than that of the CCD image sensor. Therefore, it can be said that the CMOS image sensor is more easily affected by waveform distortion or propagation delay of φSub.

Accordingly, similarly to the first exemplary embodiment, impurity induced parts 10 into which N-type impurity is induced are formed below a contact that supplies φSub to the semiconductor substrate. With this configuration, in a path in which φSub is transferred to each of photoelectric conversion parts 4 through the inside of the semiconductor substrate, resistance R1 in a direction perpendicular to the surface of the substrate can be significantly reduced. Accordingly, since waveform distortion and delay of φSub can be suppressed and the signal amount generated by the reflected light can be measured correctly, an error in the measured distance can be reduced. Similarly to the first exemplary embodiment, it is more effective to use a silicon substrate having a low resistance as the semiconductor substrate.

Note that, in the CMOS image sensor having a large circuit scale, that is, a large chip size, in order to suppress delay in a wiring layer, a plurality of signal terminals 35 of φSub is preferably disposed. In this case, similarly to the first exemplary embodiment, signal terminals 35 are preferably disposed away from one another by a uniform distance.

As described above, by using the solid-state image sensor according to each exemplary embodiment described above as the TOF type distance measuring camera, high distance measuring accuracy can be maintained while improving sensitivity or resolution, in comparison with use of the conventional solid-state image sensor.

### Third Exemplary Embodiment

In a third exemplary embodiment, a solid-state image sensor is the CCD image sensor similarly to the first exemplary embodiment, but a difference lies in a process for forming the N-type epitaxial layer formed on the semiconductor substrate. However, an object of the third exemplary embodiment is to suppress waveform distortion and delay of φSub, which is the same as the object of the first exemplary embodiment. Here, differences from the first exemplary embodiment will be mainly described.

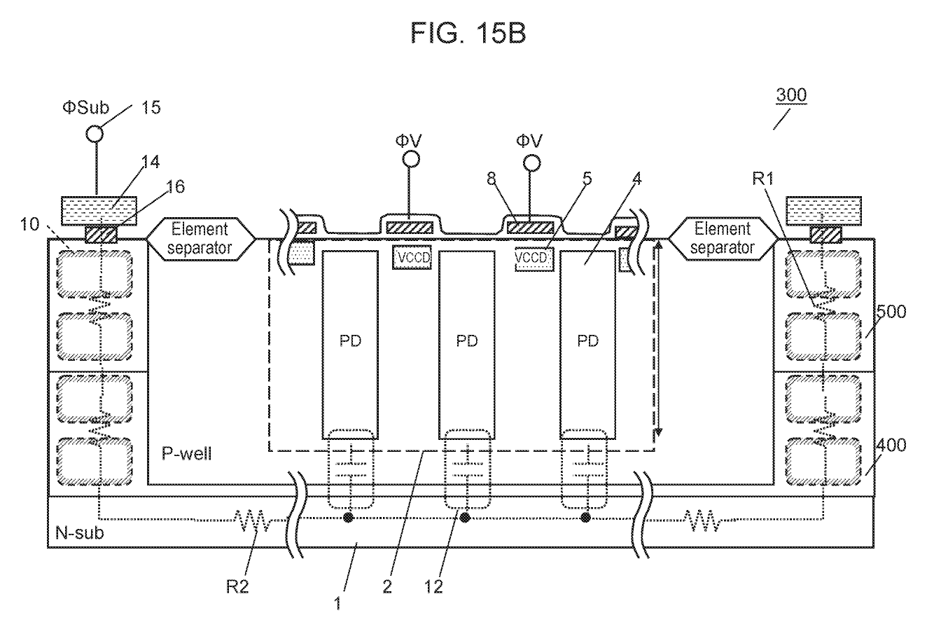

Each of FIGS. 15A and 15B is a schematic sectional view illustrating examples of a configuration and a manufacturing process of the solid-state image sensor according to the present exemplary embodiment. As illustrated in FIG. 15B, in this solid-state imaging device, for example, photoelectric conversion parts 4 and inter-pixel separators 6 that separate photoelectric conversion parts 4 are formed over first epitaxial layer 400 and second epitaxial layer 500, which are the N-type, on semiconductor substrate 1 (lying continuously over first epitaxial layer 400 and second epitaxial layer 500, in a form crossing over a boundary between first epitaxial layer 400 and second epitaxial layer 500).

Each of photoelectric conversion parts 4 formed over first epitaxial layer 400 and second epitaxial layer 500 includes first N-type layer 404 and second N-type layer 504, which are the same conductive type. Photoelectric conversion parts 4 are formed by forming second N-type layer 504 in second epitaxial layer 500, after second epitaxial layer 500 is formed on first epitaxial layer 400 in which first N-type layer 404 is formed. First N-type layer 404 is formed only in first epitaxial layer 400, but second N-type layer 504 is formed over first epitaxial layer 400 and second epitaxial layer 500, and is overlapped with a whole or a part of first N-type layer 404. First N-type layer 404 and second N-type layer 504 are electrically connected to each other.

Furthermore, on a surface of first epitaxial layer 400, a process alignment mark used for determining a position of second N-type layer 504 when second N-type layer 504 is formed, such that first N-type layer 404 and second N-type layer 504 are located at an overlapped position, when second epitaxial layer 500 is viewed from a surface thereof. It is desirable that a film thickness of the second epitaxial layer is 5 μm or less, for example. With this configuration, impurity can be implanted with high accuracy, and second epitaxial layer 500 can be surely connected to first epitaxial layer 400.

Similarly to photoelectric conversion parts 4, first impurity induced part 410 and second impurity induced part 510, which are the same conductive type, are also contained in a path in which φSub is transmitted at a peripheral part of solid-state imaging device 300. After second epitaxial layer 500 is formed on first epitaxial layer 400 in which first impurity induced part 410 is formed, second impurity induced part 510 is formed in second epitaxial layer 500. First impurity induced part 410 is formed only in first epitaxial layer 400, but second impurity induced part 510 is formed over first epitaxial layer 400 and second epitaxial layer 500. With this configuration, resistance R1 in the path in which φSub is transmitted can be significantly reduced, and particularly a resistance at an interface between first epitaxial layer 400 and second epitaxial layer 500, which easily becomes high in a process that performs epitaxial growth twice, can be suppressed. Impurity induced parts 410 and 510 can be formed by performing the N-type ion implantation up different depths several times, for example. FIG. 15B schematically illustrates a configuration example in which the N-type ions (for example, arsenic or phosphorus) are implanted up two different depths from each other, in each of first epitaxial layer 400 and second epitaxial layer 500.

FIG. 15A illustrates a part of the manufacturing process that is a process in which a part of photoelectric conversion parts 4, a part of inter-pixel separators 6, and the like are formed by using an existing lithography technology and an existing impurity doping technology, after first epitaxial layer 400 is formed on semiconductor substrate 1. At this time, impurity induced parts 410 into which the N-type impurity is induced are simultaneously formed by using the existing technologies in the peripheral part of the solid-state imaging device, that is, the path through which φSub is transmitted. Then the second epitaxial layer is formed on a surface of first epitaxial layer 400, thereby easily reducing the resistance in the transmitting path of φSub simultaneously, while forming the deep photoelectric conversion parts by using the existing technologies.

As described above, according to the present exemplary embodiment, even when the sensitivity that is important for the distance measuring sensor using the infrared light is remarkably improved by using the existing lithography technology and the existing impurity doping technology, impurity induced parts 410 and 510 into which the N-type impurity is induced are formed below contact 16 that supplies φSub to semiconductor substrate 1. With this configuration, in the path in which φSub is transferred to photoelectric conversion part 4 through the inside of semiconductor substrate 1, resistance R1 in the direction perpendicular to the surface of the substrate can be significantly reduced. Accordingly, since the waveform distortion and delay of φSub can be suppressed and the signal amount generated by the reflected light can be measured correctly, the error in the measured distance can be reduced. Furthermore, this configuration can be achieved by using the existing lithography technology and the existing impurity doping technology, and therefore introduction of new apparatuses and the like is not required.

Similarly to the first exemplary embodiment, it is more effective that resistance R2 in the horizontal direction is lowered and the plurality of first signal terminals to which φSub is applied are disposed. Further, the distance measuring sensor that can achieve both high sensitivity and high accuracy can be achieved in the same manner, also when the CMOS image sensor in the second exemplary embodiment is used.

It is noted that an application of the solid-state imaging device according to the present disclosure is not limited to the TOF type distance measuring camera, and the solid-state imaging device according to the present disclosure may be used for a distance measuring camera using another method such as a stereo method or a pattern irradiation type. Further, even in applications other than the distance measuring camera, a transmission characteristic of φSub can be improved, thereby obtaining advantageous effect such as performance improvement.

As described above, the present disclosure is preferably used for the TOF type sensor of the pulse method, but can also be used for TOF type sensors other than the pulse method (for example, a phase difference method that performs distance measurement by measuring an amount of phase delay in reflected light) to improve distance measurement accuracy.

Thus, the exemplary embodiments have been described, but the present disclosure is not limited to those exemplary embodiments. Configurations in which various variations conceived by those skilled in the art are applied to the present exemplary embodiments, and configurations established by combining components in different exemplary embodiments also fall within the scope of the present disclosure, without departing from the gist of the present disclosure.

### INDUSTRIAL APPLICABILITY

The present disclosure provides a solid-state image sensor that can be used as, for example, a distance measuring sensor with high accuracy, and therefore is useful to achieve a distance measuring camera and a motion camera, which have high accuracy, for example.

### REFERENCE MARKS IN THE DRAWINGS

1: semiconductor substrate
2: pixel array part
3: well region
4: photoelectric conversion part
5: vertical transfer part
6: inter-pixel separator
10: impurity induced part
12: vertical overflow drain structure (VOD)
14: signal wiring pattern
15: first signal terminal
15a to 15f: first signal terminal
16: contact (connecting part)
18, 18a, 18b: second signal terminal
22: pixel array part
24: photoelectric conversion part
32: vertical overflow drain structure (VOD)
34: signal wiring pattern
35: first signal terminal
100: solid-state image sensor
100A, 100B, 100C: solid-state image sensor
200: solid-state image sensor
103: infrared light source
106: solid-state image sensor
110: imaging device
300: solid-state image sensor
400: first epitaxial layer
404: first N-type layer
410: first impurity induced part
500: second epitaxial layer
504: second N-type layer
510: second impurity induced part
φSub: substrate discharge pulse signal
φV: electrode driving signal

1. A solid-state image sensor comprising:
a semiconductor substrate of a first conductive type;
photoelectric conversion parts each of which is formed in a well region, and converts reflected light from a subject to calculate a distance to the subject, into signal charges;
a pixel array part in which the photoelectric conversion parts are arranged in a matrix form;
charge transfer parts in which the signal charges are read from the photoelectric conversion parts;
a first epitaxial layer of the first conductive type formed at a surface part of the semiconductor substrate;
a second epitaxial layer of the first conductive type formed on the first epitaxial layer;
a first signal terminal to which a discharge pulsed signal that respectively defines a start and an end of an exposure time period by a fall and a rise of the discharge pulse signal is applied;
a signal wiring pattern for transmitting the discharge pulse signal applied to the first signal terminal;
a connecting part for electrically connecting the signal wiring pattern to a portion other than the well region on a surface of the semiconductor substrate; and
an impurity induced part in which the discharge pulse signal is transmitted and impurity of the first conductive type is induced, below the connecting part in the semiconductor substrate,
wherein
in the photoelectric conversion parts, when an electrode driving signal for controlling read of the signal charges from the photoelectric conversion part to the charge transfer part is high, and the discharge pulse signal is low, the signal charges are read out, and when the electrode driving signal is high and the pulsed discharge signal is high, the signal charges are discharged, and
the photoelectric conversion parts are further formed in the well region in the first epitaxial layer and the second epitaxial layer.

2. The solid-state image sensor according to claim 1, wherein
the photoelectric conversion parts are formed in the well region of a second conductive type formed at a surface part of the semiconductor substrate.

3. The solid-state image sensor according to claim 1, wherein
the photoelectric conversion parts and the impurity induced part are formed over the first epitaxial layer and the second epitaxial layer.

4. The solid-state image sensor according to claim 1, wherein
a part of the photoelectric conversion parts arranged in the matrix form and a part of the impurity induced part are formed in the second epitaxial layer, while not being formed over the first epitaxial layer and the second epitaxial layer.

5. The solid-state image sensor according to claim 1, wherein
each of the photoelectric conversion parts formed over the first epitaxial layer and the second epitaxial layer includes a first layer and a second layer, which are of a same conductive type, the second layer being formed in the second epitaxial layer, after the second epitaxial layer is formed on the first epitaxial layer in which the first layer is formed.

6. The solid-state image sensor according to claim 1, wherein
the impurity induced part formed over the first epitaxial layer and the second epitaxial layer includes a first impurity layer and a second impurity layer, which are of a same conductive type, the second impurity layer being formed in the second epitaxial layer, after the second epitaxial layer is formed on the first epitaxial layer in which the first impurity layer is formed.

7. The solid-state image sensor according to claim 1, wherein
the solid-state image sensor is used as a distance measuring sensor of a time-of-flight (TOF) type, and
the discharge pulse signal is used to control an exposure time period.

8. The solid-state image sensor according to claim 1, wherein
the semiconductor substrate is a silicon substrate having a resistance value of 0.3 Ω·cm or less.

9. The solid-state image sensor according to claim 1, wherein
the impurity induced part is formed by performing a plurality of times of implantation of ions of the first conductive type from the surface of the semiconductor substrate to different implantation depths.

10. The solid-state image sensor according to of claim 1, wherein
a plurality of the first signal terminals is disposed.

11. The solid-state image sensor according to of claim 1, wherein
the plurality of the first signal terminals is disposed, and
the plurality of the first signal terminals is disposed on both sides of the pixel array part in a row direction or in a column direction, in plan view.

12. The solid-state image sensor according to claim 1, wherein
the plurality of the first signal terminals is disposed, and
the plurality of the first signal terminals is disposed on four sides of the pixel array part, in plan view.

13. The solid-state image sensor according to claim 1 further comprising
a second signal terminal to which the electrode driving signal is applied,
wherein
the first signal terminal and the second signal terminal are disposed on one side of the pixel array part in a row direction or in a column direction, in plan view.

14. The solid-state image sensor according to of claim 1, further comprising
a plurality of the second signal terminals to which the electrode driving signal are applied, wherein
the electrode driving signal is used to control the exposure time period together with the discharge pulse signal, and
the plurality of the second signal terminals are disposed on each of both sides of the pixel array part in a row direction in plan view.

15. An imaging device comprising:
an infrared light source for irradiating a subject with infrared light; and
the solid-state image sensor according to of claim 1, which receives reflected light from the subject.
